(19) United States
(12) Patent Application Publication
(10) Pub. No.: US 2011/0095778 A1
(43) Pub. Date: Apr. 28, 2011

(54) PROBE CARD

(76) Inventors: Young Huang CHOU, Hsinchu Hsiang (TW); Wei Cheng Ku, Hsinchu Hsiang (TW)

(21) Appl. No.: 12/912,731

(22) Filed: Oct. 26, 2010

(30) Foreign Application Priority Data
Oct. 28, 2009 (TW) 098136431
Oct. 14, 2010 (TW) 099135013

(51) Int. Cl. G01R 31/00

(52) U.S. Cl. 324/756.03

(57) ABSTRACT

A probe card is provided. The probe card detaches or separates a probe assembly and a test signal generator which generates test signals from the tester and the printed circuit board, so as to form a probe system module. The probe system module is secured into a probe card module by one or more securing unit. The probe card module includes the printed circuit board. Control signals from the tester are wirelessly transmitted to the probe system module and drive the probe system module to generate the corresponding test signals. Therefore, the loss or distortion of the test signals due to having longer transmitting distances will be reduced and thus the test quality can be improved.

### FIELD OF INVENTION

The invention relates to a probe card, and especially relates to a probe card which has a probe system module able to maintain signal integrity of the test signals.

### BACKGROUND OF THE INVENTION

During a wafer testing, the tester, which communicates with a wafer through a probe card, transmits test signals to the wafer and then gets response signals from the wafer. Generally speaking, the probe card includes a plurality of precise probes. During the test, by means of the precise probes contacting with the small pads or bumps on a device under test (DUT), the test signals are transmitted from the tester to the device under test, and with the coordination of the control procedures of the probe card and the tester, the testing or measuring is thereby completed.

With improvements in technology, the structure of the probe card has become more precise and sophisticated. However, the complexity of the transmitting lines in the probe card has led to the overall transmitting distance for the test signals becoming longer. In the conventional art, the test signals are generated from the tester, transmitted through the metallic contacts or conductive lines to the probe card, passed through a printed circuit board of the probe card, and then arrived at the tip of the probes, so that the transmitting distance for the test signals is a very long path. Therefore, the loss or distortion of the test signals received by the device under test is usually caused by the multi-layered structure of the probe card, the exceeding length of the transmitting distance, or the interference from the ground wire. For the same or similar reason, the test result signals sent back from the device under test to the probe card or the tester will have some degree of signal loss, so that the test results cannot properly reflect the true test results from the device under test.

There are some related patents providing teachings upon probe cards with parallel testing capability. For example, U.S. Pat. No. 7,307,433, titled “Intelligent probe card architecture”, discloses a probe card to correct the disadvantages of a single type probe card, which probes the devices on the wafer one-by-one. This patent discloses a daughter card and other components which are in coordination to enable fan out of the test signals and power from a single channel to multiple devices under test, so as to achieve the purpose of parallel testing. U.S. Pat. No. 6,678,850, titled “Distributed interface for parallel testing of multiple devices using a single tester channel”, discloses an interface circuitry disposed on a printed circuit board of a probe card. The interface circuitry, acted as a fan-out interface for test signals, receives the test signals from a tester via a single channel, sends the test signals to a number of devices under test, and receives a plurality of response signals from the devices under test. U.S. Pat. No. 7,202,687, titled “System and methods for wireless semiconductor device testing”, discloses a probe card system which employs wireless transmission so as to increase the number of transmitting channels. Test signals are transmitted wirelessly to a plurality of probes, so that the degree of wiring complexity in the probe card will be reduced.

However, the purposes and the embodiments of U.S. Pat. No. 7,307,433 are to provide a parallel testing mechanism and to solve the problem concerning the isolation between the numbers of devices under test and between the multiple power lines. In U.S. Pat. No. 6,678,850, the interface circuitry performs a plurality of comparisons using the data values read from the devices under test and in response, returns the error values to the tester. As described above, U.S. Pat. No. 7,202,687 features the fan out of a single channel to multiple channels. In all of the aforementioned patents, the test signals are generated from the tester, the loss or distortion of the transmitting signals due to the exceeding length of the transmitting distances are still unresolved.

### SUMMARY OF THE INVENTION

From the above, the transmitting distance for the test signals to the tip of the probe is longer in the conventional probe cards. Therefore, one aspect of the present invention is to provide a probe card having a shorter transmitting distance for the test signals, so as to improve the transmission quality and maintain the clarity and integrity of the test signals received by the devices under test.

To achieve the foregoing and other aspects, the probe card of the present invention detaches or separates a test signal generator that generates test signals and a probe assembly from the tester and the printed circuit board, so as to form a probe system module. The probe system module is responsible for receiving the control signals from the tester and generating the corresponding test signals. Because the probe system module is closer to a probe assembly, the transmitting distance for the test signals is thereby shortened. As a result, the loss or distortion of the test signals is reduced and thus the test quality is improved.

In addition, the probe card of the present invention includes a probe card module, a probe system module, and at least a securing unit which is configured to secure the probe system module to the probe card module. The probe card module includes a first transceiver. The probe system module includes a probe assembly, a signal processing unit, and a second transceiver. The second transceiver is configured to wirelessly communicate with the first transceiver and to receive the control signals from the first transceiver. In response to the control signals, the signal processing unit is driven to generate and transmit the test signals to the probe assembly, and the test result signals are transmitted by the second transceiver to the first transceiver.

Besides improving the integrity of the test signals, the probe system module of the present invention can replace some of the capabilities of the tester and perform self-testing for electrical properties of the signal transmission.

The above and other aspects, features, and advantages of the present invention will become more apparent from the following detailed description when taken in conjunction with the accompanying drawings.

### BRIEF DESCRIPTION OF THE DRAWINGS

FIG. 1A shows a system architecture diagram of a probe card of an embodiment in the present invention.

FIG. 1B shows a system architecture diagram of a probe card of another embodiment in the present invention.

FIG. 2 shows a schematic diagram of a probe card of an embodiment in the present invention.

FIG. 3 shows a top view of an internal configuration in the probe system module 20 of the embodiment in FIG. 2.

FIG. 4 shows the probe system module in coordination with a computer for self testing.

### DETAILED DESCRIPTION OF THE INVENTION

In a conventional probe card, after being transmitted from the tester, the test signals would pass through a multi-layered structure of the probe card having a relatively long distance, and then arrive at the tips of the probes. Besides the contribution by the conductive lines distance, the influence due to the connection methods and the ground lines also cause the loss or distortion of the test signals. In order to resolve these problems, the probe assembly and the capability of signal processing (including the generation and transmission of test signals) are detached or separated from the other parts of the probe card, and is being combined together as a probe system module. In response to the control signals from the tester, the probe system module itself generates test signals. As a result, the transmitting distance to the tips of the probes is thereby minimized.

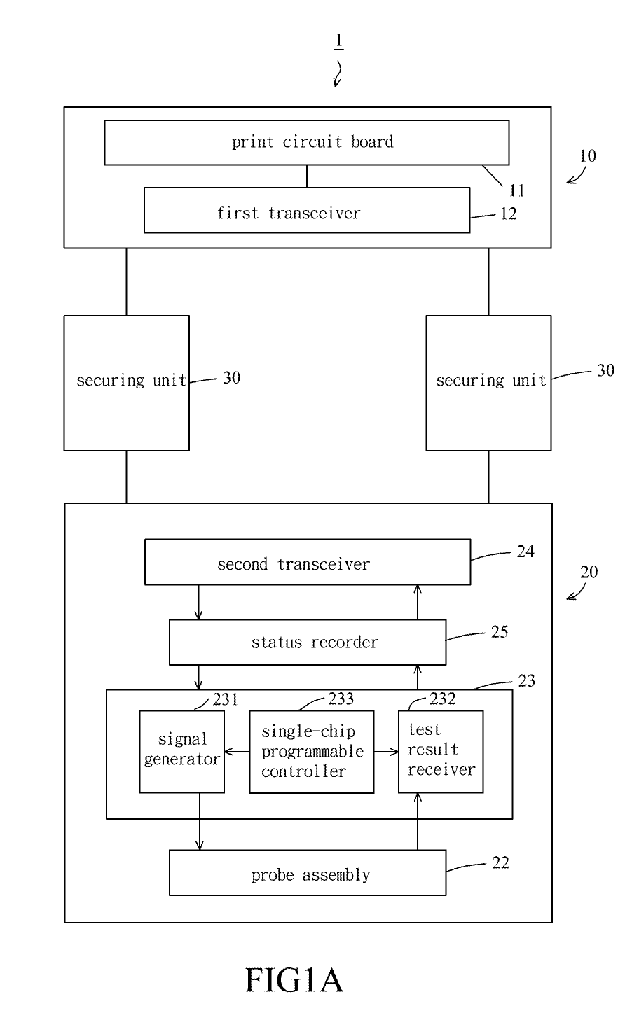

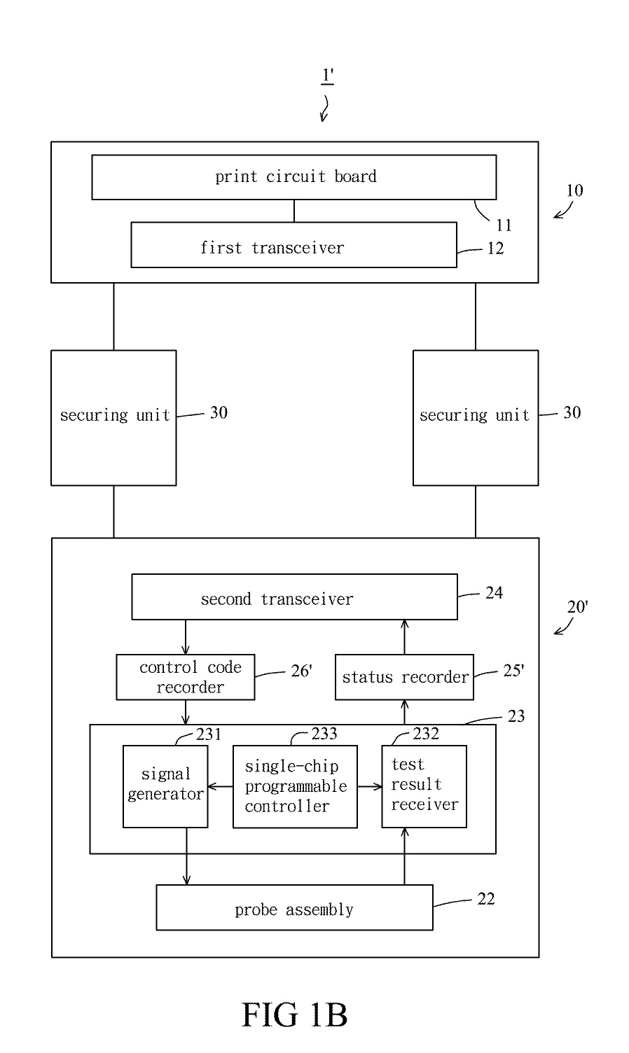

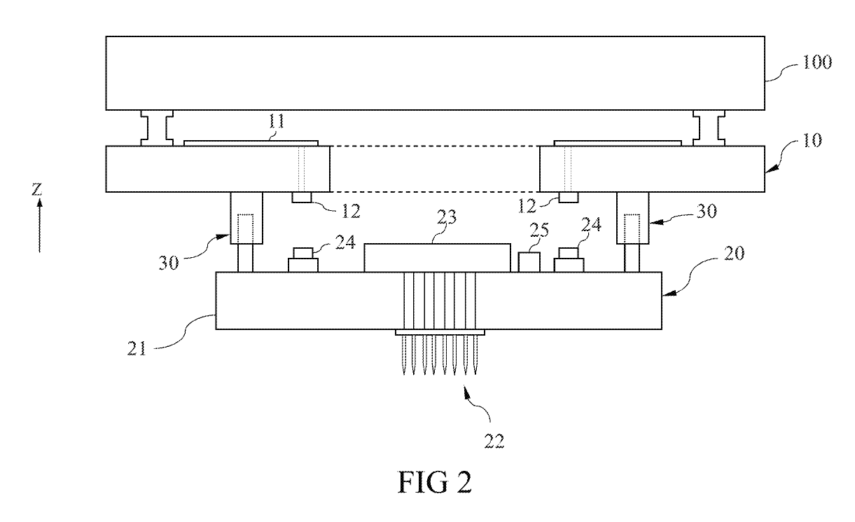

Please refer to FIG. 1A and FIG. 2. FIG. 1A and FIG. 2 show a system architecture diagram and a schematic diagram of a probe card of an embodiment of the present invention, respectively. The probe card 1 includes a probe card module 10, a probe system module 20, and one or more securing units 30. The securing units 30 secure the probe system module 20 to the probe card module 10.

The probe card module 10 includes a printed circuit board 11 and a first transceiver 12. Control signals from the printed circuit board 11 are transmitted to the first transceiver 12. After that, the control signals are transmitted to the probe system module 20 by the first transceiver 12. A person of ordinary skill in the art should appreciate that the probe card module 10 may include other known components or devices of the conventional probe card, for example: a securing device that secure the probe card to the tester 100, various connecting lines, or a structure-strengthening device. For the sake of clarifying the features of the invention, further description of these conventional components or devices is omitted.

In the above-described embodiment, the first transceiver 12 includes an digital-to-analog converter (not shown). The digital-to-analog converter can convert the digital control signals to the analog signals. Thereafter, the analog signals are transmitted into a second transceiver 24 (described in detail later). As a result, the signal transmissions would obtain improved transmission quality.

The probe system module 20, which is substantially independent of or separated from the probe card module 10, includes a base 21, a probe assembly 22 mounted on the base 21, a signal process unit 23, and a second transceiver 24. The probe assembly 22 is mounted at one side of the base 21, and forming a test surface. The second transceiver 24 is used as a communication interface between the probe system module 20 and the probe card module 10, to receive the control signals from the first transceiver and to transmit the control signals to the signal processing unit 23. On the other hand, the bidirectional signal transmission between the first transceiver 12 and the second transceiver 24 is available, so that the second transceiver 24 can send back the test result signals, which is passed through and may be pre-processed by the signal process unit 23, to the first transceiver 12 for allowing control signal analysis to be performed by the probe card module 10 or further by the tester 100. The probe assembly 22 includes a plurality of probes, and each of the probes is electrically connected to the signal processing unit 23. In response to the control signals from the probe card module 10 or further from the tester 100, the signal processing unit 23 generates the corresponding test signals which are then transmitted to the corresponding probe of the probe assembly 22 for testing the devices under test. The test result signals, responded from the devices under test, are sent back to the signal processing unit 23 via the probes of the probe assembly 22.

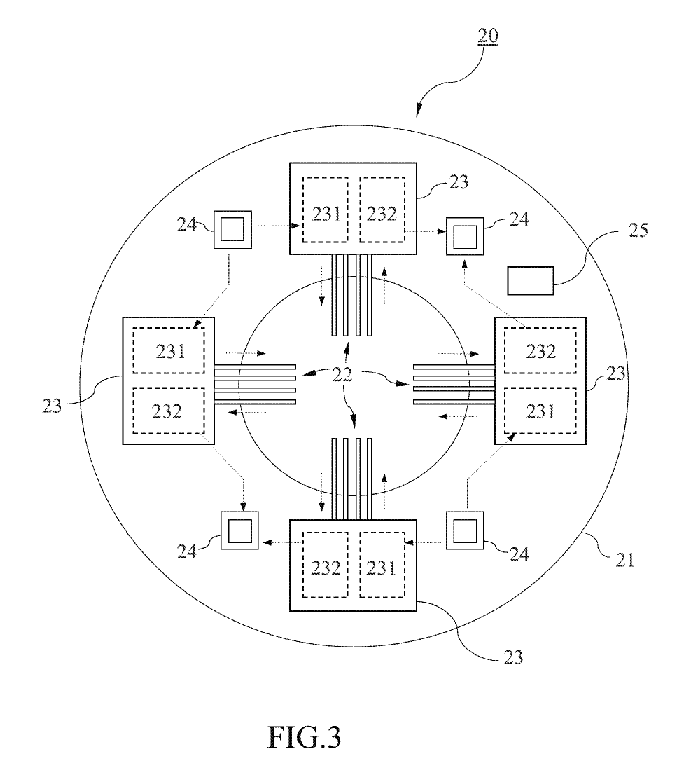

Please refer to FIG. 1A and FIG. 3 simultaneously. FIG. 3 shows a top view of an internal configuration in the probe system module 20 of the embodiment in FIG. 2. The signal processing unit 23 includes a signal generator 231 and a test result receiver 232. In response to the control signals from the first transceiver 12, the signal generator 231 generates and transmits the test signals to the probe assembly 22. The types of the test signals include, but not limited to, direct current signals (DC signals), radio frequency signals (RF signals), and analog/digital function signals. The test result receiver 232 receives the analog or digital test result signals which is sent back from the probe assembly 22. The test result signals are transmitted by the second transceiver 24 to the probe card module 10 and the tester 100. The signal processing unit 23 further includes a single-chip programmable controller 233. In response to the control signals received from the first transceiver 12, the single-chip programmable controller 233 generates a plurality of first driving signals which drive the signal generator 231 to generate the test signals. Furthermore, the single-chip programmable controller 233 can generate a plurality of second driving signals which drive the test result receiver 232 to receive and transmit the test result signals to the second transceiver 24. Thereafter, the second transceiver 24 transmits the received test result signals to the first transceiver 12. In a preferred embodiment, the signal processing unit 23 includes a digital-to-analog converter (not shown). The digital-to-analog converter can convert the digital test result signals to analog test result signals, which are transmitted to the probe card module 10.

The probe system module 20 includes a status recorder 25, which may be a memory or a register. The status recorder 25 is used as a queue for the second transceiver 24 and the test result receiver 232. Of course, a person skilled in the art can separate the queue as two units, respectively, for the transceiver 24 and the test result receiver 232. FIG. 1B shows another embodiment of the probe card 1′. The probe system module 20′ of the probe card 1′ includes a status recorder 25′ and a control code recorder 26′. Both the status recorder 25′ and the control code recorder 26′ are a plurality of memories and registers. The status recorder 25′ is a queue for the test result receiver 232, for transmitting the data from the test result receiver 232 to the second transceiver 24. The control code recorder 26′ is a queue for the second transceiver 24, for transmitting the data from the second transceiver 24 to the single-chip programmable controller 233.

In a preferred embodiment, the signal processing unit 23 is a semiconductor device having a ball-grid-array (BGA) package which can be mounted on the base 21 and electrically connected with the probe assembly 22 through the conductive line in the base 21. In an alternative embodiment, the signal processing unit 23 can be inserted into a socket mounted on the base 21; therefore, the signal processing unit 23 can be replaced by another type of signal processing units requiring of different functions. One main aspect of the invention is to resolve the loss or distortion of signals due to the longer length of transmitting distance to the probes, so that the distance between the signal processing unit 23 and the probe assembly 22 is reduced to be as short as possible. For example, the signal processing unit 23 can be embedded inside the base 21 and located near the probe assembly 22, so as to shorten the signal transmitting distance. In addition, a power supply for the probe system module 20 is also separated from the probe card module 10. The power of the probe system module 20 is supplied from, for example, a built-in battery or an external power supply. Because the power of the probe system module 20 is not supplied from the probe card module 10, the issues relating to poor electrical quality due to the complexity of the grounding structures are thereby avoided.

The signal transmission between the first transceiver 12 and the second transceiver 24 is performed by non-contact type wireless transmission, for example: radio-frequency transmission, microwave transmission, infrared transmission, or coupling transmission. Some of the common types of wireless transmission would emit higher radiation and thus interferes with the test quality, so a person of ordinary skill in the art can choose a wireless coupling mechanism which emits lower radiation, for example: magnetic coupling, electrical coupling, or optical coupling.

The probe system module 20 is secured to the probe card module 10 by the securing units 30. A person of ordinary skill in the art should appreciate there are a large number of types of securing means, such as screws or latches, for securing the probe system module 20 to the probe card module 10. In one preferred embodiment, the securing unit 30 is damping structure which can absorb external forces generated by the movements or vibrations during the test or detachment process. In another preferred embodiment, the securing unit 30 includes a horizontal adjustment mechanism which can adjust the horizontal level or the z-axis (shown in FIG. 2) movement of the probe system module 20. In other preferred embodiment, the securing unit 30 is a detachable structure. For this embodiment, the probe system module 20 can be easily detached from the securing units 30, and the flexibility in use and maintainability are improved.

The probe assembly 22 is defined as an overall assembly of all the probes containing in the probe card 1. The type of the probes can be, but not limited to, a cantilevered probe, a vertical probe, or a MEMS probe. In addition, the probe system module 20 is electrically separated from the probe card module 10. In other words, the conductive lines of the probe system module 20 are not connected to those of the probe card module 10. The probe system module 20 and the probe card module 10 are independent of and separated from each other, and are to be indirectly connected by using the securing units 30. Furthermore, the power supply of the probe system module 20 is independent from that of the probe card module 10. The power of the probe system module 20 is supplied from a built-in battery or an external power supply.

Please refer to FIG. 3. The probe system module 20 includes a plurality of probe assemblies 22, a plurality of signal processing units 23, and a plurality of second transmission units 24. The second transmission unit 24 may be a unidirectional transmission or a bi-directional transmission device. In FIG. 3, the second transmission unit 24 is a unidirectional transmission device. Some of the second transmission units 24 are responsible for transmitting the control signals to the signal processing unit 23, while the other second transmission units 24 are responsible for transmitting the test result signals to the probe card module 10. Therefore, the signal delay phenomenon due to bi-directional transmission can be avoided.

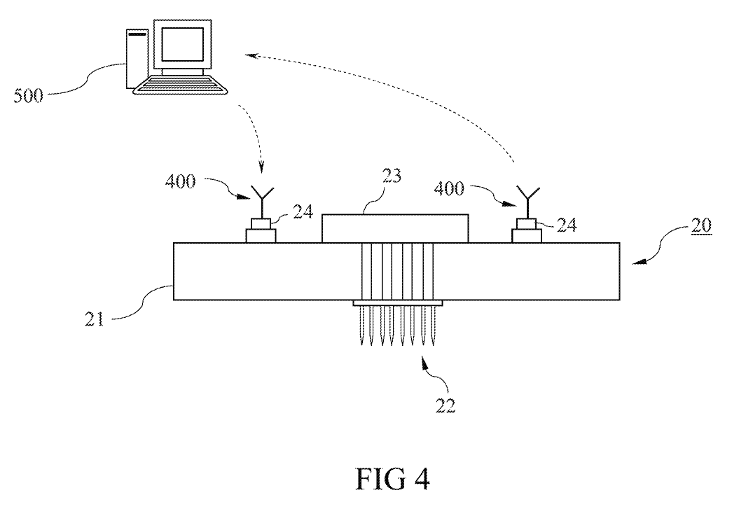

The control signals from the tester 100 can drive the probe system module 20, located near the probe assembly 22, to generate the corresponding test signals. Because the signal transmission concerning and relating to the conducted test is performed in the probe system module 20, the loss or distortion of signals is minimized, thus the clarity and integrity of the test signals received by the devices under test is thereby maintained intact. Furthermore, compared to the conventional printed circuit board, the probe system module 20 has a smaller size. By using the socket, the signal processing unit 23 can be replaced with others according to a different probe card 1 or to accommodate different test requirements, so that the probe system module 20 of the present invention has improved functional expandability. In addition, the probe system module 20 can be detached from the probe card module 10 for self-testing. For example, FIG. 4 shows that by having an antenna 400 installed, the probe system module 20 can then communicate with a computer 500 for self testing. The computer 500 is, for example, a personal computer. The computer 500, for replacing the tester 100, can generate and transmit the control signals to the signal processing unit 23 for self testing, and to assist the probe system module 20 to perform self testing and correction. Thus, even without the tester 100, the probe card 1 can perform self test and correction.

Although the description above contains many specifics, these are merely provided to illustrate the invention and should not be construed as limitations of the invention's scope. Thus it will be apparent to those skilled, in the art that various modifications and variations can be made in the system and processes of the present invention without departing from the spirit or scope of the invention.

What is claimed is:

1. A probe card, comprising:
a probe card module, the probe card module comprising a first transceiver;
a probe system module, the probe system module comprising a probe assembly, a signal processing unit, and a second transceiver, the second transceiver configured to wirelessly communicate with the first transceiver and receive a plurality of control signals from the first transceiver; and
at least a securing unit, the securing unit configured to secure the probe system module to the probe card module;
wherein in response to the control signals, the signal processing unit is driven to generate a plurality of test signals and transmit the test signals to the probe assembly for performing a test, and the test result signals from the test is transmitted by the second transceiver to the first transceiver.

2. The probe card of claim 1, wherein the signal processing unit comprises a signal generator and a test result receiver, the signal generator is configured to generate the test signals in response to the control signals and transmit the test signals to the probe assembly, and the test result receiver is configured to receive the test result signals from the probe assembly.

3. The probe card of claim 2, wherein the test signals are selected from the group consisting of direct current signals, radio-frequency signals, and analog/digital function signals.

4. The probe card of claim 2, wherein the signal processing unit comprises a digital-to-analog converter, and the digital-to-analog converter is configured to transmit the test result signals to the first transceiver in an analog mode.

5. The probe card of claim 2, wherein the signal processing unit further comprises a single-chip programmable controller, the single-chip programmable controller is configured to receive the control signals, and in response, to generate a plurality of first driving signals, which drive the signal generator to generate the test signals; and the single-chip programmable controller is configured to generate a plurality of second driving signals, which drive the test result receiver to receive and transmit the test result signals to the second transceiver, and the second transceiver transmits the test result signals to the first transceiver.

6. The probe card of claim 2, wherein the probe system module comprises a status recorder, the status recorder is configured for being used as a queue for the second transceiver and the test result receiver.

7. The probe card of claim 6, wherein the status recorder is a memory or a register.

8. The probe card of claim 2, wherein the probe system module comprises a status recorder and a control code recorder, the status recorder is configured for being used as a queue for the test result receiver; and the control code recorder is configured for being used as a queue for the second transceiver.

9. The probe card of claim 8, wherein both of the status recorder and the control code recorder are a plurality of memories or registers.

10. The probe card of claim 1, wherein the first transceiver comprises a digital-to-analog converter, and the digital-to-analog converter is configured to transmit the test result signals to the second transceiver in an analog mode.

11. The probe card of claim 1, wherein a signal transmission between the first transceiver and the second transceiver is performed by using a wireless transmission.

12. The probe card of claim 11, wherein the wireless transmission is a coupling mechanism, the coupling mechanism is selected from the group consisting of magnetic coupling, optical coupling, and an electric coupling.

13. The probe card of claim 1, wherein the securing unit is a damping structure.

14. The probe card of claim 1, wherein the securing unit comprises a horizontal adjustment mechanism.

15. The probe card of claim 1, wherein the securing unit is a detachable structure.
